(19) United States
(12) Patent Application Publication
(10) Pub. No.: US 2024/0113004 A1
(43) Pub. Date: Apr. 4, 2024

(54) CONNECTING A CHIPLET TO AN INTERPOSER DIE AND TO A PACKAGE INTERFACE USING A SPACER INTERCONNECT COUPLED TO A PORTION OF THE CHIPLET

(71) Applicant: ADVANCED MICRO DEVICES, INC., SANTA CLARA, CA (US)

(72) Inventors: GABRIEL H. LOH, BELLEVUE, WA (US); ERIC J. CHAPMAN, AUSTIN, TX (US); RAJA SWAMINATHAN, AUSTIN, TX (US)

(21) Appl. No.: 17/957,444

(22) Filed: Sep. 30, 2022

(51) Int. Cl. H01L 23/498; H01L 23/00

(52) U.S. Cl. CPC H01L 23/49833; H01L 24/16; H01L 24/32; H01L 24/73; H01L 24/92; H01L 2224/16225; H01L 2224/32225; H01L 2224/73204; H01L 2224/9211

(57) ABSTRACT

A semiconductor package assembly includes a package interface. An interposer die has a first surface and a second surface opposite to the first surface, where the first surface of the interposer is die positioned on the package interface. The interposer die includes a plurality of conductive connections between the first surface and second surface. A chiplet includes a connectivity region having conductive pathways, with a first portion of the connectivity region coupled to a conductive connection of the interposer die and a second portion of the connectivity region cantilevered from the interposer die.

### BACKGROUND

Increasing numbers of components are interconnected in semiconductor assemblies. To connect different components, some semiconductor assemblies include conductive traces parallel to a substrate on to which the components are coupled. Such conductive traces, in some variations, are above a surface of the substrate itself. While this elevation of the conductive traces above the substrate simplifies fabrication, use of such elevated conductive traces blocks power delivery to portions of a system on chip, or a die, that is coupled to the elevated conductive traces.

### BRIEF DESCRIPTION OF THE DRAWINGS

FIG. 1 is a cross-sectional view of a semiconductor assembly including chiplet that is coupled to a portion of an interposer die and to a spacer interconnect according to some implementations.

FIG. 2 is a cross-sectional view of another semiconductor assembly including a chiplet that is coupled to an interposer die and to a spacer interconnect according to some implementations.

FIG. 3 is a comparison of cross-sections of configurations for coupling a chiplet to an interposer die according to some implementations.

FIG. 4 is a cross-sectional diagram of an example integrated circuit device including a chiplet that is coupled to a portion of an interposer die and to a spacer interconnect according to some implementations.

FIG. 5 is an example computing device according to some implementations.

FIG. 6 is a flow chart illustrating an example method for manufacturing an integrated circuit device including a chiplet that is coupled to a portion of an interposer die and to a spacer interconnect according to some implementations.

### DETAILED DESCRIPTION

As semiconductor technologies further advance, stacked semiconductor devices (e.g., three dimensional integrated circuits (3DICs)), have emerged as an effective alternative to further reduce the physical size of semiconductor devices. In a stacked semiconductor device, active circuits such as logic, memory, processor circuits, and the like are fabricated on different semiconductor dies. Two or more semiconductor dies may be installed or stacked on top of one another to further reduce the form factor of the semiconductor device. To provide certain types of functionality, a stacked semiconductor device includes one or more function specific chiplets. For example, a stacked semiconductor device includes an input/output chiplet to provide input signals to the stacked semiconductor device and to provide output signals from the stacked semiconductor device.

Various types of function specific chiplets receive signals from a package interface of a stacked semiconductor device. This prevents those function specific chiplets from being stacked on another die, as such stacking would involve including through silicon vias in the other die to allow such a function specific chiplet to receive signals from the package interface of the stacked semiconductor device. Such through silicon vias would adversely affect an active portion of the die on which the function specific chiplet is stacked. Similarly, including the functions of a function specific chiplet in a die onto which another die is stacked would lead to through silicon vias in a portion of the die performing the functions of the function specific chiplet to allow the die to communicate with the other die, preventing performance of the functions of the function specific chiplet. Conventional methods place a function specific chiplet side-by-side with another die, which increases an overall area of a stacked semiconductor device and increases a latency of the function specific chiplet communicating with other dies by increasing a distance between the function specific chiplet and another die.

To decrease an overall area of a stacked semiconductor device while decreasing latency for a chiplet coupled to an interposer die to communicate with other dies, the present specification describes coupling a portion of the chiplet to a first surface of the interposer die. The first surface of the interposer die is opposite to a second surface of the interposer die that is positioned on a package substrate. This elevates the chiplet above the package substrate and results in a portion of the chiplet being cantilevered from the interposer die. To support the cantilevered portion of the chiplet, a spacer interconnect is positioned between the chiplet and the package substrate. Such a configuration reduces the overall area for a semiconductor device by repositioning the chiplet from adjacent to the interposer die to partially overlapping with the interposer die. Further, the configuration describe above allows the chiplet to receive signals or power via the spacer interconnect, rather than from through-silicon vias formed in the interposer die.

To that end, the present specification sets forth various implementations of a semiconductor package assembly including: a package interface and an interposer die having a first surface and a second surface opposite to the first surface, with the first surface of the interposer die positioned on the package interface and the interposer die including a plurality of conductive connections between the first surface and second surface. The semiconductor package assembly further includes a chiplet including a connectivity region having conducive pathways, with a first portion of the connectivity region coupled to a conductive connection of the interposer die and a second portion of the connectivity region not coupled to the interposer die. In various implementations, the first portion of the connectivity region of the chiplet is configured to communicate with the interposer die, and the second portion of the connectivity region of the chiplet is configured to communicate with the package substrate.

In some implementations, the semiconductor package assembly also includes a spacer interconnect a spacer device placed between a second portion of the connectivity region of the chiplet and the package interface, with the spacer device including spacer conductive connections coupling conductive pathways of the second portion of the connectivity region to one or more connections within the package interface. In various implementations, the spacer interconnect comprises a passive die. In some implementations, a diameter of the spacer conductive connections is different than a diameter of a connector included in the package interface. The diameter of a spacer conductive connection is smaller than the diameter of the connector included in the package interface in some implementations. In some implementations, a plurality of spacer conductive connections are coupled to the connector included in the package interface. In various implementations, a diameter of the spacer conductive connections equals a diameter of a connector included in the package interface. In some implementations, the spacer interconnect comprises a molding compound filling a distance between the second portion of the connectivity region and a surface of the package interface and filling area between and around one or more other chiplets included in the semiconductor package assembly. In some implementations, the spacer interconnect has a thickness based on a distance between second portion of the connectivity region of the chiplet and a surface of the package interface.

In some implementations the interposer die includes an active interposer die. The chiplet is configured to perform one or more input/output functions in various implementations.

The present specification further describes a method including coupling a first portion of a connectivity region of a chiplet to a conductive connection of an interposer die a second surface of the interposer die, the conductive connection between the second surface and a first surface of the interposer die, the connectivity region having one or more conductive pathways and a second portion of the connectivity region cantilevered from the interposer die. The method further coupling a spacer interconnect to a second portion of connectivity region of the chiplet and to a package interface coupled to the first surface of the interposer die, the spacer interconnect including one or more spacer conductive connections coupled to one or more of the conductive pathways of the second portion of the connectivity region and coupled to a connector within a package interface to which the interposer die is coupled in some implementations. In some implementations, the spacer interconnect comprises a passive die. In some implementations, the wherein a diameter of a spacer conductive connection is smaller than a diameter of the connector included in the package interface. A plurality of spacer conductive connections are coupled to the connector included in the package interface in some implementations. In various implementations, a diameter of the spacer conductive connections equals a diameter of a connector included in the package interface. The spacer interconnect has a thickness based on a distance between second portion of the connectivity region of the chiplet and a surface of the package interface in various implementations. In some implementations, the interpose die is an active interposer die.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “front” “back,” “top,” “bottom,” and the like, are used herein for ease of description to describe one element or feature's relationship to another element(s) or feature(s) as illustrated in the figures. Similarly, terms such as “front surface” and “back surface” or “top surface” and “back surface” are used herein to more easily identify various components, and identify that those components are, for example, on opposing sides of another component. The spatially relative terms are intended to encompass different orientations of the device in use or operation in addition to the orientation depicted in the figures.

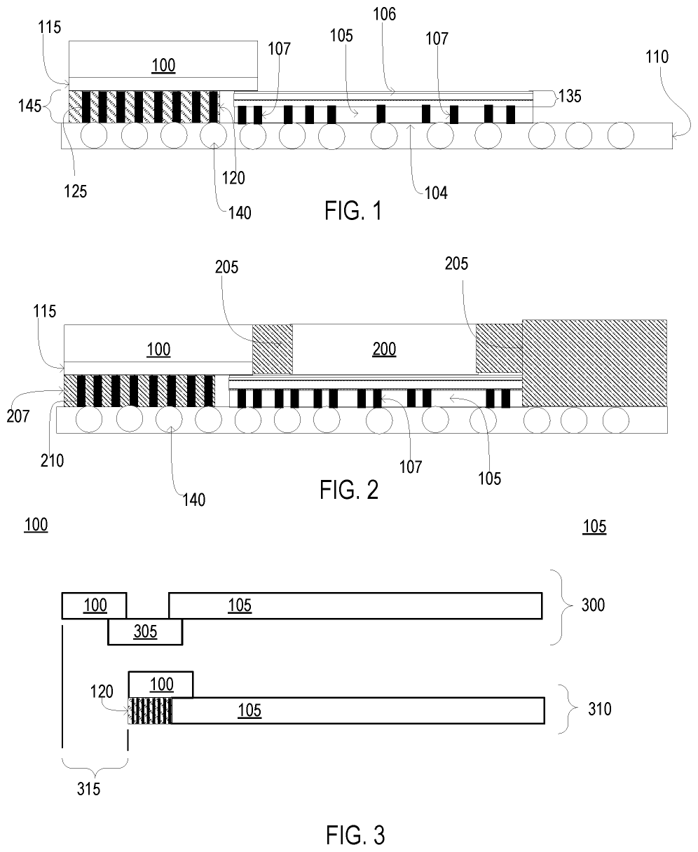

FIG. 1 is a cross-sectional view of a semiconductor assembly including a chiplet 100 that is coupled to an interposer die 105 and to a spacer interconnect 120. In various implementations, the chiplet 100 implements one or more specific functions for a system on chip (SoC). For example, chiplet 100 performs one or more input/output functions for a SoC, allowing communication between one or more other dies in the semiconductor assembly and components external to the semiconductor assembly. In other implementations, the chiplet 100 performs one or more direct memory access (DMA) functions for the semiconductor assembly, performs one or more address translation functions for the semiconductor assembly, performs one or more input-output memory management functions for the semiconductor assembly, performs one or more security functions for the semiconductor assembly, or performs one or more compression functions for the semiconductor assembly. However, in other implementations, the chiplet 100 performs any suitable function, or combination of functions, for the semiconductor assembly.

The interposer die 105 receives power or other signals and routes power to other components of the semiconductor assembly, such as other dies or chiplets included in the semiconductor assembly. The interposer die 105 has a first surface 104 and a second surface 106 that is opposite to and parallel to the first surface 104, with a plurality of conductive connections 107 between the first surface 104 and the second surface 106. In some implementations, the interposer die 105 is an active interposer including logic for routing signals, power, and the like, received by the interposer die 105 to one or more of the conductive pathways. Such routing logic allows the interposer die 105 to direct signals, power, and the like, received by the interposer die 105 to other components. In some implementations, the first surface 104 of the interposer die 105 is a front surface of the interposer die 105 and the second surface 106 of the interposer die 105 is a back surface of the interposer die 105. Alternatively, in other implementations, the first surface 104 of the interposer die 105 is a back surface of the interposer die 105, while the second surface 106 of the interposer die 105 is a front surface of the interposer die 105.

In various implementations, the interposer die 105 receives power and ground through a package interface 110, which also couples the interposer die 105 to a substrate (not shown) in the implementation shown in FIG. 1. In various implementations, the package interface 110 includes connectors 140, such as copper pillars, solder bumps (e.g., C4 bumps), or other types of package interconnects. One or more of the connectors 140 are coupled to conductive connections 107 of the interposer die 105, allowing coupling of the interposer die 105 to a component external to the semiconductor assembly through a connector 140 and a conductive connection 107 of the interposer die 105. In various implementations, one or more connectors 140 are coupled to a power supply and to a conductive connection 107 of the interposer die 105, allowing the interposer die 107 to receive power from the power supply.

Additionally, the interposer die 105 includes one or more connection layers 135. In some examples, the connection layers 135 include layers of metallization and interlevel dielectric material, as well as conductive structures such as vias, traces, and pads. In these examples, the one or more connection layers 135 form connections between the circuit components composed in the die substrate to implement the functional circuit blocks of the interposer die 105. For example, the one or more connection layers 135 implement a die-level redistribution layer structure created during the die fabrication process, such as a back end of line (BEOL) structure. In another example, the one or more connection layers 135 are implemented with bond pads or bond pad vias. In other examples, the one or more connection layers 135 are redistribution layers (RDL) included in the interposer die 105. In other examples, the one or more connection layers 135 are implemented with more than one structure (e.g., BEOL and bond pad vias). In the fabrication process, interconnects may be created with very fine line/space pitches of less than 1 μm, thus allowing for high density connections. In these examples, the one or more connection layers also include bonding sites to which metal connectors (e.g., die pads, microbumps, Controlled Collapse Chip Connection (C4) bumps) may be attached, either during the fabrication process or in a post-fabrication process such as die packaging. One or more of the connection layers 135 are coupled to one or more of the conductive connections 107 of the interposer die 105 in various implementations. Coupling a conductive connection 107 of the interposer die 105 to a connection layer 135 allows the interposer die 105 to distribute a signal or power received via the conductive connection 107 to other components of the semiconductor assembly through the connection layer 135 of the interposer die 105. For purposes of illustration, FIG. 1 shows one or more connection layers 135 nearest to the second surface 106 of the interposer die 105, while the interposer die 105 includes one or more connection layers near the first surface 104 of the interposer die 105, which include bonding sites to which metal connectors (e.g., die pads, microbumps, Controlled Collapse Chip Connection (C4) bumps) may be attached in various implementations.

In the example shown by FIG. 1, a first portion of the chiplet 100 is positioned on a portion of the second surface 106 of the interposer die 105. In various implementations, a first portion of a first surface of the chiplet 100 is coupled to a portion of the second surface 106 of the interposer die 105. The first surface of the chiplet 100 is nearest to the package interface 110 in various implementations. The chiplet 100 includes a connectivity region 115 proximate to the first surface of the chiplet 100. The connectivity region 115 includes conductive pathways that are generally parallel to the second surface 106 of the interposer die 105. In various implementations, the conductive pathways comprise layers of metallization and interlevel dielectric material, as well as conductive structures such as vias, traces, and pads. In some examples, as shown in FIG. 1, the first portion of the chiplet 100 is face-to-second (F2B) bonded to the portion of the second surface 106 of the interposer die 105 through various bonding techniques such as hybrid bonding, thermocompression bonding, solder reflow, and other techniques. However, it is further contemplated that the chiplet 100 may be face-to-face (F2F) bonded to the interposer die 105 through various bonding techniques such as hybrid bonding, thermocompression bonding, solder reflow, and other techniques.

A first portion of the connectivity region 115 within the first portion of the chiplet 100 is coupled to one or more conductive connections 107 of the interposer die 105. However, a second portion of the connectivity region 115 is not coupled to the chiplet 100. Thus, the second portion of the connectivity region 115 is cantilevered from the chiplet 100 and above a surface of the package interface 110. In some implementations, one or more conductive connections 107 of the interposer die 105 are directly coupled to one or more conductive pathways of the first portion of the connectivity region 115. In other implementations, one or more conductive pathways of the first portion of the connectivity region 115 are coupled to one or more connection layers 135 of the interposer die 105, with the one or more connections layers 135 coupled to one or more conductive connections 107 of the interposer die 105. For example, the first portion of the connectivity region 115 in the first portion of the chiplet 100 is coupled to the one or more conductive connections 107 through the second surface 106 of the interposer die 105. As shown in FIG. 1, the conductive connections 107 of the interposer die 105 provide connection from one or more connection layers 135 of the interposer die 105, or from the second surface 106 of the die to first surface 104 of the interposer die 105. Hence, the conductive connections 107 provide signals (and power and ground) on one surface of the interposer die 105 to an opposing surface of the interposer die 105 for interconnection to another component. In the example shown by FIG. 1, the second surface 106 of the interposer die 105 includes one or more connection layers 135, including a metallization layer or multiple levels of metallization and dielectric layers that is created on the second surface 106 of the die for connecting the conductive connections 107 to another component. The conductive connections 107 are through-die vias in various implementations. In some examples, the conductive connections 107 are fabricated before device layers (transistors, capacitors, resistors, etc.) are patterned onto the interposer die 105. In some examples, the conductive connections 107 are fabricated after the individual devices are patterned but before the one or more connection layers are created on the interposer die 105. In some examples, the conductive connections 107 are fabricated after (or during) the fabrication of the one or more connection layers. After formation, the conductive connections 107 may be selectively filled or plated with conductive material (e.g., copper) to create interconnects. In some examples, the diameter of the conductive connections 107 is less than 10 μm. In some examples, the conductive connections 107 are buried, such that the bulk of the substrate is to be ground or etched away to expose a conductive connection 107. The conductive connections 107 provide high density, short channel, wide interconnects useful for die partitioning and die stacking. In some implementations, one or more of the conductive connections 107 are coupled to one or more of the connection layers 135 of the interposer die 105.

As shown in FIG. 1, a spacer interconnect 120 is placed between to a second portion of the first surface of the chiplet 100 that includes the second portion of the connectivity region 115 of the chiplet 100 and the package interface 110. The spacer interconnect 120 is a passive die in some implementations, while in other implementations. In various implementations, the passive die comprises silicon that does not include active components, but includes the spacer conductive connections 125 further described below. In another implementation, the spacer interconnect 120 is a dielectric material. In other implementations the spacer interconnect 120 is a die including includes one or more active components. In various implementations, the spacer interconnect 120 is coupled to an end 130 of the first surface of the chiplet 100 that is opposite an end of the chiplet 100 to which the interposer die 105 is coupled. For example, the spacer interconnect 120 is coupled to the second portion of the connectivity region 115 of the chiplet 100. Additionally, the spacer interconnect 120 includes spacer conductive connections 125 coupling one or more conductive pathways of the connectivity region 115 within the second portion of the chiplet 100 to one or more connections 140 within the package interface 110. For example, one of more of the spacer conductive connections 125 of the spacer interconnect 120 are coupled to one or more connectors 140 within the package interface 110 and to one or more of the conductive pathways of the connectivity region 115 of the second portion of the chiplet 100. In various implementations, the spacer conductive connections 125 of the spacer interconnect 120 are through vias in the spacer interconnect 120, such as through silicon vias in the spacer interconnect 120. In some implementations, the through vias are selectively filled or plated with conductive material (e.g., copper) to create interconnects.

The spacer conductive connections 125 extend through a thickness 145 of the spacer interconnect 120. The thickness 145 of the spacer interconnect 120 is based on a vertical distance between the first surface of the chiplet 100 and a surface of the package interface 110. Hence, the spacer conductive connections 125 allow coupling of the chiplet 100 to connectors 140 included in the package interface 110 for coupling components external to a semiconductor assembly to components within the semiconductor assembly. Further, the spacer interconnect 120 offsets a height differential between the surface of the package interface 110 and the first surface of the chiplet 100. In the example shown by FIG. 1, the thickness 145 of the spacer interconnect 120 is based on a distance between the first surface of the chiplet 100 and an upper surface of the package interface 110. For example, the spacer interconnect 120 has a thickness 145 that equals the distance between a topmost surface of the package interface 110 that is parallel to the chiplet 100 and to the first surface of the chiplet 100. As another example, the spacer interconnect 120 has a thickness 145 that is within a threshold amount of the distance between the topmost surface of the package interface 110 that is parallel to the first surface of the chiplet 100 and the first surface of the chiplet 100. Hence, the thickness 145 of the spacer interconnect 120 is capable of being customized for different implementations to account for different distances between the first surface of the chiplet 100 and a surface of the package interface 110 of a semiconductor assembly.

In different implementations, a diameter of the spacer conductive connections 125 included in the spacer interconnect 120 differs from a diameter of the conductive connections 107 within the interposer die 105. In some implementations, the spacer conductive connections 125 in the spacer interconnect 120 have a smaller diameter than a diameter of a connector 140 in the package interface 110, so multiple spacer conductive connections 125 are ganged together to reduce impedance for delivering signals from a connector 140 of the package interface 110 to the chiplet 100. For example, the spacer conductive connections 125 have a minimum diameter for a fabrication method used to create the semiconductor assembly. In other implementations, a diameter of the spacer conductive connections 125 is determined based on a diameter of the connectors 140 of the package interface 110. As an example, a diameter of a spacer conductive connection 210 equals a diameter of a connector of the package interface 110. In another example, a diameter of the spacer conductive connections 125 is within a threshold amount of the diameter of the connectors 140 of the package interface 110, resulting in relatively wide spacer conductive connections 125 that improve resiliency to electromigration-related long-term wear.

One or more of the spacer conductive connections 125 are coupled to one or more connectors 140 of the package interface 110. This electrically couples one or more spacer conductive connections 125 to components external to a semiconductor assembly through the one or more connectors 140 of the package interface 110. Hence, the spacer conductive connections 125 and the connector 140 of the package interface 110 allow the chiplet 100 to be coupled to one or more components external to the semiconductor assembly including the chiplet 100.

As shown in FIG. 1, positioning the first portion of the chiplet 100 on the portion of the second surface of the interposer die 105 reduces an overall area of the semiconductor assembly compared to techniques where the chiplet 100 and the interposer die 105 are next to each other in a common plane. Positioning the spacer interconnect 120 between the second portion of the chiplet 100 and the package interface 110 also simplifies providing power or other signals from the package interface 110 to the chiplet 100. Additionally, this configuration prevents perforating the chiplet 100 with through vias, while maintaining a majority of the first surface of the chiplet 100 exposed for connection to connectors 140 within the package interface 110. Further, positioning the first portion of the chiplet 100 on the second surface 106 of the interposer die 105 elevates the chiplet 100 above the package interface 110, reducing overall semiconductor assembly size and allowing an increased yield of semiconductor assemblies per wafer.

FIG. 2 is a cross-sectional view of a semiconductor assembly including a chiplet 100 that is coupled to an interposer die 105 and to a spacer interconnect. In the example shown by FIG. 2, an additional die 200 is stacked on top of interposer die 105. In various implementations, the additional die 200 is coupled to the one or more connection layers 135 nearest the second surface 106 of the interposer die 105. The additional die 200 implements one or more additional component functions for a system on chip (SoC). For example, the interposer die 105 is an active interposer die configured to direct signals or power to other components of the semiconductor assembly, such as to the additional die 200, while the additional die 200 performs one or more computational functions for the semiconductor assembly.

As further described above in conjunction with FIG. 1, a first portion of the chiplet 100 is positioned on a portion of the second surface of the interposer die 105. In various implementations, a first portion of a first surface of the chiplet 100 is positioned on the portion of the second surface 106 of the interposer die 105. In the example shown by FIG. 2, when fabricating the semiconductor assembly, a molding compound 205 (or other material) is used to fill areas between different chiplets or components included in the semiconductor assembly. As shown in FIG. 2, a portion 207 of the molding compound 205 fills an area between the package interface 110 and the first surface of the chiplet 100. Additionally, other portions of the molding compound 205 fills areas between chiplets or other components of the semiconductor assembly. In the example shown by FIG. 2, the molding compound 205 fills an area between the chiplet 100 and the additional die 200, as well as fills an area around the additional die 200 and an area around the interposer die 105. Hence, the portion 207 of the molding compound 205 between the first surface of the chiplet 100 and the package interface 110 functions as the spacer interconnect 120 in FIG. 2

One or more of the spacer conductive connections 210 are coupled to one or more connectors 140 of the package interface 110. This electrically couples one or more spacer conductive connections 210 to components external to a semiconductor assembly through the one or more connectors 140 of the package interface 110. Hence, the spacer conductive connections 210 and the connector 140 of the package interface 110 allow the chiplet 100 to be coupled to one or more components external to the semiconductor assembly including the chiplet 100.

Thus, in the example of FIG. 2, the spacer interconnect 120 comprises molding compound 205, with spacer conductive connections 210 included in the molding compound 205 to couple one or more pathways of the connectivity region 115 of the chiplet 100 to one or more connectors 140 within the package interface. Hence, one or more of the spacer conductive connections 210 of the spacer interconnect 120 are coupled to one or more of the conductive pathways of the connectivity region 115 of the chiplet 100 and to one or more of the connectors 140 of the package interface 110. In various implementations, the spacer conductive connections 210 of the spacer interconnect 120 when molding compound 205 is used as the spacer interconnect 120 are through-mold vias in the molding compound 205. In some implementations, the through-mold vias are selectively filled or plated with conductive material (e.g., copper) to create interconnects.

FIGS. 1 and 2 show different implementations for creating the spacer interconnect 120 used to fill an area between the package interface 110 and the first surface of the chiplet 100. In the example of FIG. 1, the spacer interconnect 120 is capable of being independently constructed and included in the semiconductor assembly. In the example of FIG. 2, the spacer interconnect 120 is created during assembly of the semiconductor assembly by constructing through-mold vias for the spacer conductive connections 210 of the spacer interconnect 120 during fabrication of the semiconductor assembly.

FIG. 3 is a comparison of cross-sections of configurations for coupling a chiplet 100 to an interposer die 105. For purposes of illustration, FIG. 3 shows a conventional configuration 300 where the chiplet 100 and the interposer die 105 are positioned side by side. In the conventional configuration 300, the function specific chiplet is coupled to the interposer die 105 through an interconnect die 305. Hence, in the conventional configuration 300, the chiplet 100 and the interposer die 105 are side-by-side in a common plane, with the interconnect die 305 coupled to a first surface of the chiplet 100 and to a first surface of the interposer die 105. For example, in the conventional configuration 300, the first surface 105 of the interposer die 105 and the first surface of the chiplet 100 are in a common plane, with portions of both coupled to the interconnect die 305. A portion of the interconnect die 305 is coupled to a portion of the first surface of the chiplet 100 and to a portion of the first surface of the interposer die 105.

In contrast, configuration 310 couples the chiplet 100 to the interposer die 105 as further described above in conjunction with FIGS. 1 and 2. In configuration 210, a first portion of the chiplet 100 is coupled to the interposer die 105, as further described above in conjunction with FIGS. 1 and 2. For example, a first portion of a first surface of the chiplet 100 is coupled to a portion of a second surface 106 of the interposer die 105, with the second surface 106 of the interposer die 106 opposite to first surface 104 and nearest to a package interface (not shown). In configuration 310, the spacer interconnect 120, further described above in conjunction with FIGS. 1 and 2, is coupled to the first surface of the chiplet 100. As further described above in conjunction with FIGS. 1 and 2, the spacer interconnect 120 offsets a height differential between the first surface of the chiplet 100 coupled to the second surface of the interposer die 105 and a plane including the first surface of the interposer die 105.

As shown by FIG. 3, coupling the first portion of the chiplet 100 to the interposer die 105 in configuration 310 rather than positioning the chiplet 100 and the interposer die 105 side by side in configuration 300 reduces an overall width for the combination of the interposer die 105 and the chiplet 100. In FIG. 3, configuration 310 reduces the width of the combination of the interposer die 105 and the chiplet 100 by a distance 315 relative to configuration 300. As shown in FIG. 3, by coupling the first portion of a first surface of the chiplet 100 to the portion of a second surface 106 of the interposer die 105, configuration 300 shortens the area used to couple the chiplet 100 to the interposer die 105 relative the conventional configuration 300 where the interposer die 105 and the chiplet 100 are positioned next to each other and coupled together via an interconnect die 305 by the distance 315.

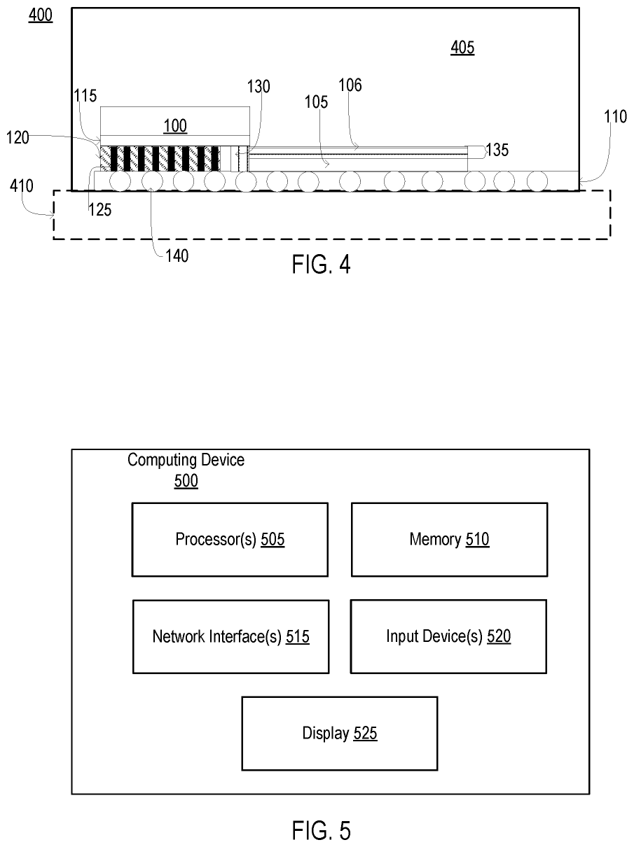

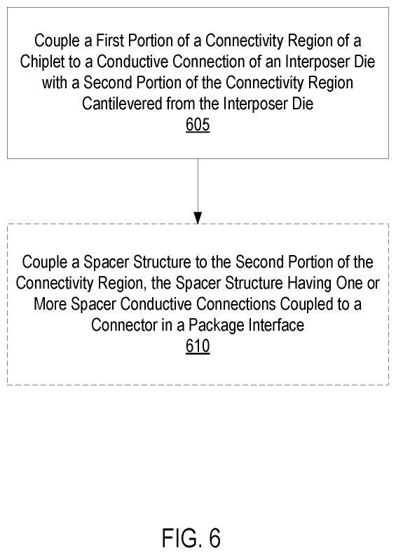

FIG. 4 is a cross-sectional diagram of an example integrated circuit device 400 including a chiplet 100 that is coupled to an interposer die 105 and to a spacer interconnect 120 in accordance with some implementations of the present disclosure. The example integrated circuit device 400 can be implemented in a variety of computing devices, including mobile devices, personal computers, peripheral hardware components, gaming devices, set-top boxes, smart phones, and the like (as shown in FIG. 6). The example integrated circuit device 400 of FIG. 4 includes a semiconductor assembly 405 including a chiplet 100 and an interposer die 105, as further described above in conjunction with FIGS. 1-3. The interposer die 105 has a first surface 104 and a second surface 106 that is parallel to and opposite to the first surface 104. A first portion of the chiplet 100 is coupled to the interposer die 105. In various implementations, a first portion of a first surface of the chiplet 100 is coupled to a portion of the second surface 106 of the interposer die 105. A spacer interconnect 120 is coupled to a second portion of the first surface of the chiplet 100. The spacer interconnect 120 is silicon in some implementations, while in other implementations, the spacer interconnect 120 is a dielectric material. In various implementations, the spacer interconnect 120 is coupled to an end of the first surface of the chiplet 100 that is opposite an end of the chiplet 100 to which the interposer die 105 is coupled. Additionally, the spacer interconnect 120 includes conductive connections 125 that are generally perpendicular to the connectivity region 115 of the chiplet 100.

As an example, the semiconductor assembly 405 includes one or more processors 505 of a computing device 500 as shown in FIG. 5. The computing device 500 is implemented, for example, as a desktop computer, a laptop computer, a server, a game console, a smart phone, a tablet, and the like. In addition to one or more processors 505, the computing device 500 includes memory 510. The memory 510 includes Random Access Memory (RAM) or other volatile memory. The memory 510 also includes non-volatile memory such as disk storage, solid state storage, and the like.

In some implementations, the computing device 500 also includes one or more network interfaces 515. In some implementations, the network interfaces 515 include a wired network interface 515 such as Ethernet or another wired network connection as can be appreciated. In some implementations, the network interfaces 515 include wireless network interfaces 515 such as WiFi, BLUETOOTH®, cellular, or other wireless network interfaces 515 as can be appreciated. In some implementations, the computing device 500 includes one or more input devices 520 that accept user input. Example input devices 520 include keyboards, touchpads, touch screen interfaces, and the like. One skilled in the art will appreciate that, in some implementations, the input devices 520 include peripheral devices such as external keyboards, mouses, and the like.

In some implementations, the computing device 500 includes a display 525. In some implementations, the display 525 includes an external display connected via a video or display port. In some implementations, the display 525 is housed within a housing of the computing device 500. For example, the display 525 includes a screen of a tablet, laptop, smartphone, or other mobile device. In implementations where the display 525 includes a touch screen, the display 525 also serves as an input device 520.

The semiconductor assembly 405 is coupled to a substrate 410. The substrate 410 is a portion of material that mechanically supports coupled components such as the semiconductor assembly 405. In some implementations, the substrate 410 also electrically couples various components mounted to the substrate 410 via conductive traces, tracks, pads, and the like. For example, the substrate 410 electrically couples a component of the semiconductor assembly 405 to one or more other components via a connective trace and a solder joint formed from a solder ball coupled to a conductive pad, such as through connectors 140 in a package interface 110 of the semiconductor assembly 405. One or more of the spacer conductive connections 125 are coupled to a connector 140 to couple the chiplet 100 to one or more components external to the semiconductor assembly 405 in various implementations.

In some implementations, the substrate 410 includes a printed circuit board (PCB), while in other implementations the substrate 410 is another semiconductor device, like semiconductor assembly 405 (which may include active components therein). In some implementations, the connectors 140 coupling the semiconductor assembly 405 to the substrate 410 are included in a socket (not shown), where the semiconductor assembly 405 is soldered to or otherwise mounted in the socket. In other implementations, as shown in FIG. 4, the connectors 140 of the package interface 110 directly couple the semiconductor assembly 405 is directly coupled to the substrate 410 via a direct solder connection or other connection as can be appreciated. In some implementations, the semiconductor assembly 405 is coupled to the substrate 410 using a land grid array (LGA), pin grid array (PGA), or other packaging technology as can be appreciated.

For further explanation, FIG. 6 sets forth a flow chart illustrating an example method for manufacturing a chiplet 100 that is coupled to an interposer die 105 and to a spacer interconnect 120. The method shown in FIG. 6 includes coupling 605 a first portion of a connectivity region 115 of the chiplet 100 to one or more conductive connections 107 on a second surface of an interposer die 105 that is opposite to and parallel to a first surface of the interposer die 105. A second portion of the connectivity region 115 of the chiplet 100 is cantilevered from the interposer die 105. Hence the first portion of the connectivity region 115 of the chiplet is coupled to a conductive connection 107 of the chiplet, while the second portion of the connectivity region 115 is not coupled to the interposer die 105 is not coupled to the interposer die 105, causing a portion of the chiplet 100 other than the first portion of the connectivity region 115 to overhang the interposer die 105. The one or more conductive connections 107 are between the first surface of the interposer die 105 and the second surface of the interposer die 105. The connectivity region 115 includes at least one conductive pathway coupled to at least one conductive connection 107, as further described above in conjunction with FIG. 1. In some implementations, the chiplet is configured to perform one or more input/output functions. Further, in some implementations, the interposer die 105 is an active interposer.

In some implementations, the method further includes coupling 610 a spacer interconnect 120 is coupled to the second portion of the connectivity region 115 of the chiplet 100. The spacer interconnect 120 is coupled to a package interface 110 that is opposite to the second portion of the connectivity region 115. Hence, the spacer interconnect 120 fills a distance between the second portion of the connectivity region 115, which is cantilevered from the interposer die 105, and the package interface 110. The spacer interconnect 120 includes one or more spacer conductive connections 125 coupled to one or more conductive pathways of the connectivity region 115 within the second portion of the connectivity region 115 of the chiplet 100. The one or more spacer conductive connections 125 are also coupled to a connector 140 included in the package interface 110. In various implementations, the spacer interconnect 120 is a passive die (i.e., a die that does not include any active components). In other implementations, the spacer interconnect 120 is molding compound filling a distance between the first surface of the chiplet and the package interface. The molding compound also fills area between and around one or more other chiplets included in the semiconductor package assembly including the chiplet 100 and the interposer die 105, as further described above in conjunction with FIG. 2. The spacer conductive connections 125 are through-mold vias in some of these implementations.

In various implementations, a diameter of a spacer conductive connection 125 equals a diameter of a connector 140 included in the package interface 110. In other implementations, the diameter of a spacer conductive connection 125 is less than the diameter of the connector 140 included in the package interface 110. If the diameter of a spacer conductive connection 125 is less than the diameter of the connector 140 included in the package interface 110, a plurality of spacer conductive connections 125 are coupled to the connector 140 included in the package interface 110. The spacer interconnect 120 has a thickness based on a distance between the first surface of the chiplet 100 including the connectivity region 115 and a surface of the package interface 110 determines a thickness of the spacer interconnect 120 in various implementations.

In view of the explanations set forth above, readers will recognize that manufacturing a semiconductor assembly including a die that is coupled to an interconnect die that is coupled to a spacer interconnect allows the die to be coupled to another component having a different height than the die or to another component having differing temperature constraints than the die. Additionally, coupling the die to the interconnect die that is coupled to the spacer interconnect simplifies connection of the die to other components when the semiconductor assembly is a stacked semiconductor assembly by including interconnect die during fabrication of the semiconductor assembly. Further, coupling a second surface of the die to an interconnect die that is coupled to a spacer interconnect allows the first surface of the die to remain unobstructed, simplifying delivery of power, ground, or other signals to the first surface of the die.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A semiconductor package assembly comprising:
a package interface;
an interposer die having a first surface and a second surface opposite to the first surface, the first surface of the interposer die positioned on the package interface, the interposer die including a plurality of conductive connections between the first surface and second surface; and
a chiplet including a connectivity region having conducive pathways, with a first portion of the connectivity region coupled to a conductive connection of the interposer die and a second portion of the connectivity region cantilevered from the interposer die.

2. The semiconductor package assembly of claim 1 further comprising:
a spacer interconnect placed between a second portion of the connectivity region of the chiplet and the package interface, the spacer interconnect including spacer conductive connections coupling conductive pathways of the second portion of the connectivity region to one or more connections within the package interface.

3. The semiconductor package assembly of claim 2, wherein the spacer interconnect comprises a passive die.

4. The semiconductor package assembly of claim 2, wherein a diameter of the spacer conductive connections is different than a diameter of a connector included in the package interface.

5. The semiconductor package assembly of claim 4, wherein the diameter of a spacer conductive connection is smaller than the diameter of the connector included in the package interface.

6. The semiconductor package assembly of claim 5, wherein a plurality of spacer conductive connections are coupled to the connector included in the package interface.

7. The semiconductor package assembly of claim 2, wherein a diameter of the spacer conductive connections equals a diameter of a connector included in the package interface.

8. The semiconductor package assembly of claim 2, wherein the spacer interconnect comprises a molding compound filling a distance between the second portion of the connectivity region and a surface of the package interface and filling area between and around one or more other chiplets included in the semiconductor package assembly.

9. The semiconductor package assembly of claim 2, wherein the spacer interconnect has a thickness based on a distance between the second portion of the connectivity region of the chiplet and a surface of the package interface.

10. The semiconductor package assembly of claim 1, wherein the interposer die comprises an active interposer die.

11. The semiconductor package assembly of claim 1, wherein the chiplet is configured to perform one or more input/output functions.

12. The semiconductor package assembly of claim 1, wherein the first portion of the connectivity region of the chiplet is configured to communicate with the interposer die, and the second portion of the connectivity region of the chiplet is configured to communicate with a package substrate to which the interposer die is coupled.

13. A method comprising:
coupling a first portion of a connectivity region of a chiplet to a conductive connection of an interposer die a second surface of the interposer die, the conductive connection between the second surface and a first surface of the interposer die, the connectivity region having one or more conductive pathways and a second portion of the connectivity region cantilevered from the interposer die.

14. The method of claim 13, further comprising:
coupling a spacer interconnect to a second portion of connectivity region of the chiplet and to a package interface coupled to the first surface of the interposer die, the spacer interconnect including one or more spacer conductive connections coupled to one or more of the conductive pathways of the second portion of the connectivity region and coupled to a connector within a package interface to which the interposer die is coupled.

15. The method of claim 14, wherein the spacer interconnect comprises a passive die.

16. The method of claim 14, wherein the wherein a diameter of a spacer conductive connection is smaller than a diameter of the connector included in the package interface.

17. The method of claim 14, wherein a plurality of spacer conductive connections are coupled to the connector included in the package interface.

18. The method of claim 14, wherein a diameter of the spacer conductive connections equals a diameter of a connector included in the package interface.

19. The method of claim 14, wherein the spacer interconnect has a thickness based on a distance between second portion of the connectivity region of the chiplet and a surface of the package interface.

20. The method of claim 13, wherein the interposer die comprises an active interposer die.
